(19) United States
(12) Patent Application Publication
(10) Pub. No.: US 2008/0122061 A1
(43) Pub. Date: May 29, 2008

(54) SEMICONDUCTOR CHIP EMBEDDED IN AN INSULATOR AND HAVING TWO-WAY HEAT EXTRACTION

(75) Inventor: Darvin Renne Edwards, Garland, TX (US)

Correspondence Address: TEXAS INSTRUMENTS INCORPORATED, P O BOX 655474, M/S 3999, DALLAS, TX, 75265, US

(73) Assignee: Texas Instruments Incorporated, Dallas, TX (US)

(21) Appl. No.: 11/564,325

(22) Filed: Nov. 29, 2006

(51) Int. Cl. H01L 23/48

(52) U.S. Cl. 257/690

(57) ABSTRACT

A semiconductor chip (101) embedded in an insulating layer (102) of a sheet-like substrate (110), made of alternating layers of thermally insulating and conductive materials, has the heat flowing from the active chip surface through metal bumps (111, etc.) to a first metal layer (144) positioned in proximity, and from the passive chip surface through metal-filled vias (130, etc.) to a second metal layer (143) positioned in proximity. The metal layers operate as heat spreaders. From the heat spreaders, the thermal energy flows through metal-filled vias (120; 130) to the substrate surfaces. On one or both substrate surfaces may be metal plates (150; 260); they may have spots metallurgically suitable for attaching solder bumps. They may connect to external heat sinks.

The present invention is related in general to the field of semiconductor devices and processes and more specifically to thermally enhanced configurations of substrates with embedded active semiconductor chips, the configurations offering two-way heat extraction.

### DESCRIPTION OF THE RELATED ART

Removing the thermal heat generated by active components belongs to the most fundamental challenges in integrated circuit technology. Coupled with the ever shrinking component feature sizes and increasing density of device integration is an ever increasing device speed, density of power and thermal energy generation. In order to keep the active components at their optimum (low) operating temperatures and speed, this heat must continuously be dissipated and removed to outside heat sinks. This effort, unfortunately, becomes increasingly harder, the higher the energy density becomes.

In known technology, the most effective approach to heat removal focuses on thermal transport through the thickness of the semiconductor chip from the active surface to the passive surface. The passive surface, in turn, is attached, for example, to the chip mount pad of a metallic leadframe so that the thermal energy can flow into the chip mount pad of the metallic leadframe. When properly formed, this leadframe can act as a heat spreader to an outside heat sink.

From a standpoint of thermal efficiency, however, this approach has shortcomings when the chip is embedded in insulating material since cooling the active chip is an issue. The heat generated by active components and traversing the thickness of the semiconductor chip in order to exit from the chip, is facing the thermal barrier of the substrate material (typically a plastic polymer).

### SUMMARY OF THE INVENTION

Applicant realized that for semiconductor chips surrounded by a body of thermally insulting material, the most effective technical solution for removing the operational heat generated by active components is to remove the heat by a two-way heat extraction structure.

A sheet-like substrate is composed of alternating layers of thermally insulating and conductive materials, wherein the insulating layers have the same material. A semiconductor chip embedded in an insulating layer of this substrate, has the heat flowing from the chip surface with the active components through metal bumps to a first metal layer positioned in proximity, and further from the passive chip surface through metal-filled vias to a second metal layer positioned in proximity. The metal layers operate as heat spreaders. From the heat spreaders, the thermal energy flows through metal-filled vias to the substrate surfaces. On one or both substrate surfaces may be metal plates; they are metallurgically prepared for attaching solder bumps. The heat can thus flow through the attached solder bumps into external heat sinks or other means of removal. In the substrate, one or more metal layer may also serve electrically as ground potential or to supply power.

The heat extraction structure is based on fundamental physics and on design concepts flexible enough to be applied for different semiconductor product families and a wide spectrum of design and assembly variations. The structure not only meets high thermal and electrical performance requirements, but also achieves improvements towards the goals of enhanced process yields and device reliability.

The technical advances represented by the invention, as well as the objects thereof, will become apparent from the following description of the preferred embodiments of the invention, when considered in conjunction with the accompanying drawings and the novel features set forth in the appended claims.

### BRIEF DESCRIPTION OF THE DRAWINGS

FIG. 1A is a schematic cross section of a sheet-like substrate of alternating layers of thermally insulating and conductive materials with semiconductor chips embedded in an insulating layer according to an embodiment of the invention.

FIG. 1B is a schematic cross section of a substrate laminated with thermally insulating and conductive layers, a semiconductor chip embedded in an insulating layer and thermally connected to heat spreaders according to an embodiment of the invention.

FIG. 2 is a schematic cross section of a substrate laminated with thermally insulating and conductive layers, a semiconductor chip embedded in an insulating layer and thermally connected to heat spreaders according to another embodiment of the invention.

FIG. 3 is a schematic cross section of a sheet-like substrate of alternating layers of thermally insulating and conductive materials with semiconductor chips embedded in an insulating layer according to an embodiment of the invention and with a heat sink and external devices attached to a substrate surface.

### DETAILED DESCRIPTION OF THE PREFERRED EMBODIMENTS

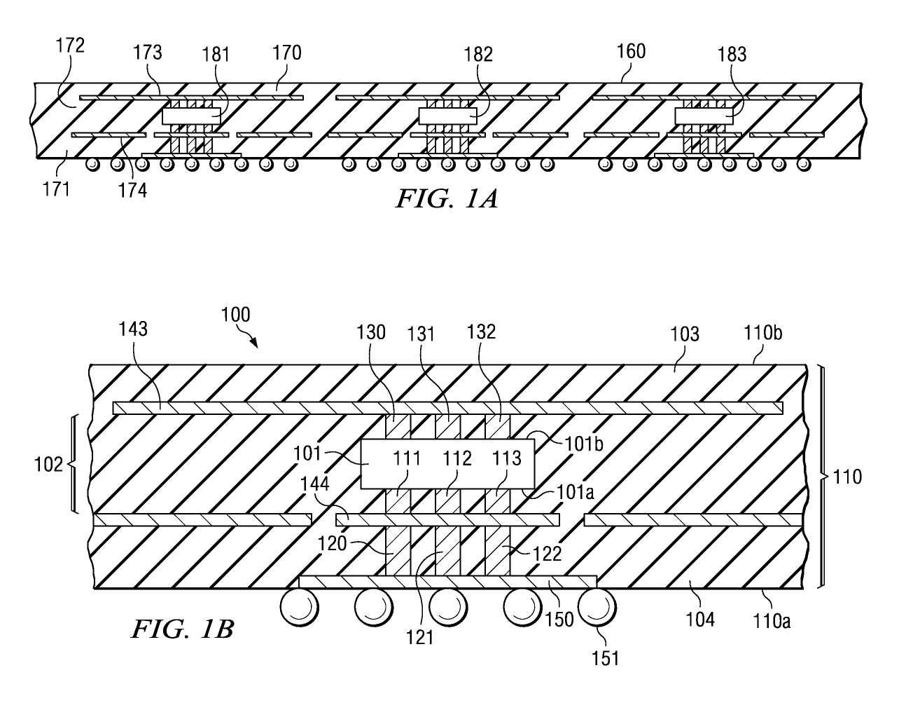

FIG. 1A shows a sheet-like substrate 160 made of alternating layers of thermally conductive and thermally insulating materials (more precisely, the thermally “insulating” material has some, but very low thermal conductivity). The conductive layers are made of the same material (preferably copper), and the insulating layers are made of the same material (preferably PCB). In the example of FIG. 1, the insulating layers have different thicknesses—layer 172 has a greater thickness than layers 170 and 171—while the conductive layers 173 and 174 have equal thickness. Embedded in one of the insulating layers (172) are a number of semiconductor chips 181, 182, 183, etc. Both surfaces of these chips have metallic bodies to thermally connect them to the nearest conductive layers, which operate as heat spreaders for the thermal energy generated by the chips during device operation. The structure is illustrated in more detail by the magnified view of a portion of substrate 160 in FIG. 1B.

FIG. 1B illustrates schematically an embodiment of the invention, generally designated 100, for improving both the thermal conductance and the temperature gradient to enhance the thermal flux vertically away from a semiconductor chip 101 embedded in thermally insulating material. In FIG. 1B, the insulating material surrounding chip 101 is a layer 102, electrically insulating and thermally of very low conductivity, in a sheet-like substrate 110 laminated by alternating layers 102, 103, 104, etc. made of a material of thermally very low conductivity, and layers 143, 144, etc. made of a material of thermally high conductivity. Thermal energy is extracted from the heat-generating electrically active components on chip surface 101a (the “active” chip surface) by metal bumps 111, 112, 113, etc., and metal-filled vias 120, 121, 122, etc. In addition, thermal energy, which is transported through the chip thickness, is carried away from the passive chip surface 101b by metal-filled vias 130, 131, 132, etc. (the “passive” surface refers to the chip surface opposite the surface with the electrically active components).

The preferred metal for the layers of high thermal conductivity is copper; while copper alloys may be used, relatively pure copper is preferred. The thermal conductivity of pure copper is about 386 W/(m·° C.). The layers of low thermal conductivity are preferably made of a polychlorinated biphenyl compound (PBC), frequently with glass fillers; PBC has an in-plane thermal conductivity between about 0.65 to 0.8 W/(m·° C.), a factor of about 500 lower than the thermal conductivity of copper. The out-of-plane conductivity of laminates is even less, about 0.15 to 0.3 W/(m·° C.). Alternatively, the thermally “insulating” layers may be made of FR-4 of various glass fiber contents; the thermal conductivity of FR-4 is about 0.3 W/(m·° C.) and thus about three orders of magnitude lower than the thermal conductivity of copper.

Embedded in plastic material of low thermal conductivity, the thermal energy generated by operating the active components of chip 101 would increase the temperature in the neighborhood of the components and throughout the semiconductor chip rapidly, if the energy would not be transported away by the connectors and heat spreaders.

In FOURIER's approach to solving the differential equation of thermal conductance, the thermal flux Q per unit of time is equal to the product of thermal conductivity λ multiplied by the gradient of temperature T, in the direction of decreasing temperature, and by the area q perpendicular to the temperature gradient:

dQ/dt=−λ·(grad T)·q,

where Q is the vector (in magnitude and direction) of thermal flux, and λ is the thermal conductivity, a materials characteristic. The thermal flux is in the direction of the temperature difference and is proportional to the magnitude of that difference.

When, over the length l, the temperature drop is steady and uniform from the high temperature T2 to the low temperature T1, then (grad T) reduces to (T2−T1)/l:

dQ/dt=−λ·(q/l)·(T2−T1).

λ·(q/l) is called the thermal conductance, and the inverse value l/(λ·q) is called thermal resistance (in analogy to OHM's law).

In the present invention, the improvement of λ·q is provided by the high thermal conductivity (preferably copper) and the geometry of conductors 110, etc; 120, etc; 130, etc.; the improvement of (grad T) is provided by the relatively low temperature of heat spreaders 143, 144, etc. Both contributions result in enhanced thermal flux vertically away from the heat-generating active components on the active surface of the semiconductor chip and the passive surface of the semiconductor chip.

The laminated sheet-like substrate 110 includes alternating layers of low thermal conductivity material and high thermal conductivity material. The thermally very low-conductivity and electrically insulating PBC layers 102, 103, 104, etc. may have equal thickness, or, as in FIG. 1B, not-equal thickness. Alternatively, the layer material may include FR-4 or FR-5 type materials, or polyimide-based compounds, or other polymers. FIG. 1B shows an example, wherein layer 102 has a greater thickness than layers 103 or 104, since it serves to embed chip 101.

In addition to the enhanced thermal flux vertically away from the active chip surface, the laminated structure of the sheet-like substrate 110 offers the possibility of conducting thermal energy in the opposite direction through the semiconductor material of the chip to its passive surface 101b and beyond into heat spreader 143. Thermal modeling has shown that the thermal flux away from the passive chip surface adds at least about 5% thermal enhancement to the thermal device performance.

In the preferred embodiment of the invention illustrated in FIG. 1B, the sheet-like substrate 110 of alternating layers of thermally low conductivity materials (102, 103, 104, etc.) and thermally high conductivity materials (143, 144, etc.) has a first surface 110a and a second surface 110b. A semiconductor chip 101 with its active surface 101a and its passive surface 101b is embedded in insulating layer 102 so that a first conductive layer 144 extends between the active chip surface 101a and the first substrate surface 110a; in addition, a second conductive layer 143 extends between the passive chip surface 101b and the second substrate surface 110b.

Metal bumps (preferably consisting of copper) 111, 112, 113, etc. connect the active chip surface 101a to the first conductive layer 144. This layer acts as a heat spreader (and may electrically be at ground potential). Metal-filled vias 120, 121, 122, etc. connect the first conductive layer 144 to the first substrate surface 110a. The preferred metal for filling the vias is copper.

Further, on surface 110a may be a metal plate 150 (for example, copper) serving as another heat spreader. In addition, plate 150 may have metallurgical surface areas (for instance, a thin gold layer) suitable for attachment of reflow metal bumps such as solder. FIG. 1B depicts some solder balls 151 attached to plate 150; the solder balls may serve as connecting elements to external heat sinks; they may also serve electrically as connectors to ground potential.

As illustrated in FIG. 1B, a number of metal-filled vias 130, 131, 132, etc. connect the passive chip surface 101b to the second conductive layer 143, which acts as a heat spreader. The thermal flux carried away by the metal-filled vias 130, 131, etc. and distributed by the heat spreader 143 improves the thermal performance of the device substantially.

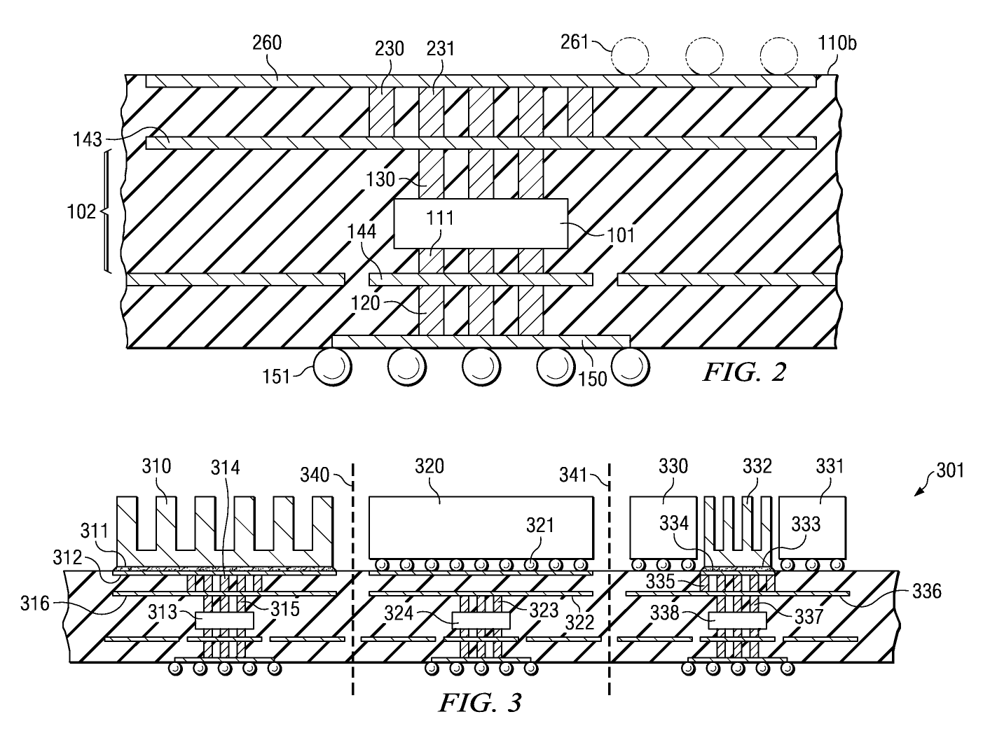

Thermal modeling determines the number and the diameter of vias 130 etc. needed to optimize the thermal flux from the passive chip surface to the heat spreader 143. The vias through the insulating material may be formed by laser drilling, or chemical etching, or any other suitable method. The preferred metal for filling the vias is copper. The filling step may be performed by an electroless plating technique. The attachment to layer 143 can be accomplished by soldering or by pressure contact. An additional improvement of the thermal device performance by enhancing the thermal flux and the thermal gradient is described in FIG. 2.

The embodiment of the invention depicted in FIG. 2 includes metal-filled vias 230, 231, etc. These vias are preferably made of copper and connect the second conductive layer 143 to the second substrate surface 110b. Positioned on surface 110b may be a metal plate 260 (for example, copper) serving as another heat spreader. In addition, plate 260 may have metallurgical surface areas (for instance, a thin gold layer) suitable for attachment of reflow metal bumps such as solder. FIG. 2 depicts some solder balls 261 attached to plate 260; the solder balls may serve as connecting elements to electrical ground or to external devices such as memory components. For connection to external heat sinks, it is preferable to perform the attachment using thermally conductive adhesives such as thermal grease or epoxy.

Examples of devices and heat sinks attached to a sheet-like substrate 301, which include the thermal structures described in FIGS. 1B and 2, are illustrated in FIG. 3. A heat sink 310 is attached by thermally conductive adhesive 311 to metal plate 312, which is thermally connected by metal-filled vias 314 to heat spreader 316 and further by metal-filled vias 315 to the passive surface of chip 313.

A semiconductor device 320, such as a memory component, is attached by solder balls 321 to the surface of substrate 301. Inside the substrate is a heat spreader, which is thermally connected by metal-filled vias 323 to the passive surface of chip 324.

Semiconductor components 330 and 331 are attached by solder balls to the surface of substrate 301. Further, a heat sink 332 is attached by thermally conductive adhesive 333 to plate 334; plate 334 is thermally connected by metal-filled vias 335 to heat spreader 336 and further by metal-filled vias 337 to the passive surface of chip 338. Inside substrate 301, heat spreader 336 extends under the areas occupied by components 330 and 331.

By sawing or another cutting operation along separation lines 340 and 341, the semiconductor devices may be singulated into discrete units.

While this invention has been described in reference to illustrative embodiments, this description is not intended to be construed in a limiting sense. Various modifications and combinations of the illustrative embodiments, as well as other embodiments of the invention, will be apparent to persons skilled in the art upon reference to the description. As an example, external heat sinks may be attached to the first substrate surface, the second substrate surface, or both surfaces directly using thermal grease or epoxy. It is therefore intended that the appended claims encompass any such modifications or embodiments.

I claim:

1. A semiconductor device comprising:
a sheet-like substrate of alternating layers of thermally insulating and conductive materials, the insulating layers made of the same material, the substrate having a first and a second surface;
a semiconductor chip having an active and a passive surface embedded in an insulating layer of the substrate so that a first conductive layer extends between the active chip surface and the first substrate surface, and a second conductive layer extends between the passive chip surface and the second substrate surface;
metal bumps connecting the active chip surface to the the first conductive layer;
metal-filled vias connecting the first conductive layer to the first substrate surface; and
metal-filled vias connecting the passive chip surface to the second conductive layer.

2. The device according to claim 1 further including metal-filled vias connecting the second conductive layer to the second substrate surface.

3. The device according to claim 1 further including metal reflow bumps attached to the metal-filled vias or to thermally conductive plates at the first substrate surface.

4. The device according to claim 1 further including metal reflow bumps attached to the metal-filled vias or to thermally conductive plates at the second substrate surface.

5. The device according to claim 1 wherein the thermally insulating layers are selected from a group consisting of polychlorinated biphenyl (PCB) compounds, FR-4, FR-5, and related compounds.

6. The device according to claim 1 wherein the thermally conductive layers are made of copper or copper alloys.

7. The device according to claim 1 wherein the metal filling the vias includes copper.
